(19) United States
(12) Patent Application Publication
(10) Pub. No.: US 2015/0207006 A1
(43) Pub. Date: Jul. 23, 2015

(54) SYSTEM AND METHOD FOR TRAPPING LIGHT IN A SOLAR CELL

(71) Applicant: TEL Solar AG, Trubbach (CH)

(72) Inventor: Luc Fesquet, Morges (CH)

(73) Assignee: TEL Solar AG, Trubbach (CH)

(21) Appl. No.: 14/159,002

(22) Filed: Jan. 20, 2014

(51) Int. Cl. H01L 31/054; H01L 31/20

(52) U.S. Cl. CPC H01L 31/0547; H01L 31/202; H01L 31/0543

(57) ABSTRACT

This application relates to systems and methods for improving solar cell efficiently by enabling more light to be captured by the absorber layer. The reflector layer in a solar cell may be designed to reflect light back into the absorber layer that has already passed through the absorber layer. The reflector layer may include a surface protrusion that has a surface that has an angle of approximately 45 degrees. Incident light is reflected from that surface towards the absorber layer or towards the reflector layer which, in turn, reflects the light back towards the absorber layer or the silicon stack. The light may be reflected at an angle that enables the light to have total internal reflection within the silicon layer (e.g., absorber layer, μc-Si layer, and a-Si layer).

### FIELD OF DISCLOSURE

This disclosure relates to solar photovoltaic conversions devices. More particularly to a method and apparatus for improving the energy conversion efficiency in a solar cell device using solar cell design that enables a higher amount of light to be converted to energy by trapping the light in the solar cell.

### BACKGROUND OF THE INVENTION

Solar photovoltaic conversions devices can convert light into electrical energy using an absorber layer that uses photons from incident light to create electron-hole pairs. Generally, the absorber lay is relatively thin to enable the electrons and holes to reach membrane layer by making the absorber layer thickness smaller than the diffusion lengths of the charge carriers. As a result, light may not be totally absorbed by the absorber layer in a single pass. The absorber layer may be thickened to absorb more light, but this increases cost of the solar cell device. Another approach may be to design a solar cell that diffuses the light more broadly across the absorber layer. However, the random scattering causes the light path to increase which results in a limitation on energy conversion by letting light escape from the solar cell. Accordingly, solar cell designs that prevent light from escaping may be desirable.

### SUMMARY

Broadly, converting solar energy to electrical energy is based on photons of incident radiation (e.g., light) generating electron-hole pairs within the silicon layer(s) of a solar cell to force charge carriers in the silicon layer(s) to move (e.g., current flow). The silicon layer may include an absorber layer with p-type silicon layer(s) and n-type silicon layer(s) on either side. The electron and holes generated in the absorber layer should reach the p-type or n-type silicon layer. This movement can be accomplished by making the absorber layer thinner than the diffusion lengths of the electrons and holes. Generally, below the silicon layer may be a reflector layer that reflects light back into the silicon layer to generate additional electron-hole pairs. However, the reflected light may escape the silicon layer and may not further contribute to electron-hole pair generation. This disclosure describes systems and methods for trapping reflected light (e.g., photons) within the silicon layer to increase electron-hole pair generation per unit of light. Trapping may be explained using the total internal reflection principle.

Total internal reflection of a propagating wave (e.g., light) can occur when a wave attempts to travel between a propagating medium that has a higher refractive index than an adjacent propagating medium. However, total internal reflection may also depend on the incident angle of the wave. For example, total internal reflection may occur when the incident angle is greater than a critical angle that may be dependent upon the refractive index of each propagating medium. In this way, light may be trapped within a propagating medium as long as the incident angle is greater than the critical angle. As a result, trapped light (e.g., photons) may generate more electron-hole pairs in the silicon layer than a single or double pass of a light through the silicon layer.

In one embodiment, the solar cell may comprise a glass layer or substantially transparent layer, a silicon layer(s), and a reflector layer. The glass layer may also include a light concentration layer or component that directs incident light through the glass layer and the silicon layer to a focal point in the reflector layer. The silicon layer may include a reflection notch that may be substantially filled by the reflector layer and adjacent to the focal point. The reflection notch may be configured to reflect at least a portion of the incident light towards the boundary of the silicon layer and the reflector layer. When the refractive index of the silicon layer may be higher than the refractive index of the reflector layer then total internal reflection may occur. The geometry of the reflection notch may be configured to reflect at least a portion of the incident light such that the incident angle of the reflected light at the silicon-reflector layer boundary is greater than the critical angle. In this way, light may be trapped within the silicon layer per the total internal reflection principle.

The reflection notch may be formed in the silicon layer(s) using a variety of techniques that are optimized to form a reflective surface. The reflective surface may be designed to reflect incident light towards silicon-reflector layer interface so that the reflected light may be totally reflected at the silicon-reflector layer interface. The reflection notch may be generated by selective etching (e.g., wet or dry etch), selective imprinting, or selective formation of topology.

In one embodiment, selective formation of topology may be implemented by altering the substrate surface of a first solar cell layer to impact the formation of a second solar cell layer that may be deposited on the first solar cell layer. For example, the glass substrate layer may be etched to form a 3-dimensional pattern on the surface. Subsequent solar cells layer may conform to the pattern and form a reflection notch that is aligned with the light concentration module on the glass layer surface.

Described herein are several embodiments related to the current density control across the anode assembly. Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

The features within the drawings are numbered and are cross-referenced with the written description. Generally, the first numeral reflects the drawing number where the feature was first introduced, and the remaining numerals are intended to distinguish the feature from the other notated features within that drawing. However, if a feature is used across several drawings, the number used to identify the feature in the drawing where the feature first appeared will be used. Reference will now be made to the accompanying drawings, which are not necessarily drawn to scale and wherein:

FIG. 1 illustrates a representative embodiment of a solar cell environment and a solar cell design described in one or more embodiments of the disclosure.

FIG. 2 illustrates a solar cell with a light concentration component and a focal point of the light concentration component as described in one or more embodiments of the disclosure.

FIG. 3 illustrates a solar cell and a path of light through the solar cell as described in one or more embodiments of the disclosure.

FIG. 4 illustrates a portion of the solar cell the path of light reflected within the solar cell as described in one or more embodiments of the disclosure.

FIG. 5 illustrates a solar cell that includes a plurality of light reflection features as described in one or more embodiments of the disclosure.

FIG. 6 illustrates another embodiment of a solar cell as described in one or more embodiments of the disclosure.

FIG. 7 illustrates another embodiment of a solar cell as described in one or more embodiments of the disclosure.

FIGS. 8A-8B illustrates a flow diagram of a solar cell manufacturing method with accompanying illustrations as described in one or more embodiments of the disclosure.

### DETAILED DESCRIPTION

Disclosed herein include systems and methods for a solar cell design that reflects light within the silicon layer(s) of the solar cell. The topography of the silicon layer(s) and the reflector layer are configured to reflect incident light along the silicon layer(s).

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other.

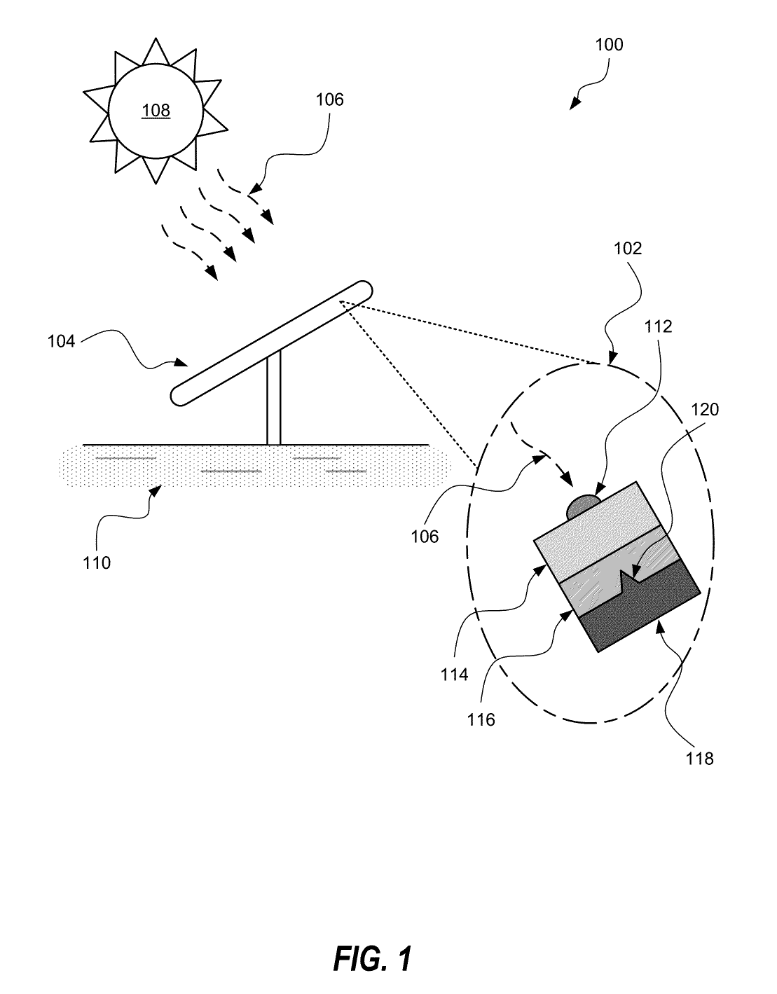

FIG. 1 illustrates a solar cell environment 100 and a solar cell design 102 that may be used in used in a solar conversion panel 104. Generally, a solar panel 104 receives light 106 (e.g., photons) from the sun 108 to convert the light 106 into electrical energy for electrical devices (not shown). In this embodiment, the solar panel 104 is installed in a ground 110 site, but this solar cell design 102 is not limited to solar panels 104 installed in the ground 110. For example, the solar panel 104 may mounted on a building (not shown) or home (not shown) or anywhere light 106 or electromagnetic radiation may be found. Another embodiment of the solar panel 104 may be embedded in an electrical device (not shown) to generate electrical current to power the device or store in a battery. The electrical device may include, but is not limited to, smart phones, tablets, laptop computers, lighting fixtures, automobiles, and/or any wireless mobile device.

The solar cell design 102 may include, but is not limited to, a light concentration component 112, a substantially transparent layer 114 (e.g., glass), a silicon layer(s) 116 that use light 106 (e.g., photons) to generate electrical energy, and a reflector layer 118.

In this embodiment, a reflection notch 120 may be incorporated into the interface of the silicon layer 116 and the reflector layer 118. The light concentration component 112 may focus, direct, or concentrate the light 106 towards the reflection notch 120. The light 106 may be reflected by the reflection notch 120 towards the silicon-reflector interface. The light 106 may be reflected towards the glass-silicon interface. When the incident angle (not shown) of the light 106 at the glass-silicon interface is greater than a critical angle (not shown) will enable at least a majority of the light 106 to be reflected back within the silicon layer 116. The critical angle (not shown) may be determined based, at least in part, on the principle of total internal reflection which enables propagating waves (e.g., light 106) to completely reflect from an interface of two wave mediums, such as the silicon layer 116 and the reflector layer 118. The principle of total internal reflection will be described in greater detail in the description of the remaining figures.

In other embodiments, the solar cell design 104 may include additional layers (e.g., transparent conductive oxides, etc.) or components to generate electrical energy. The silicon layer 116(s) 116 may include multiple silicon layers 116 that may be used to generate electrical energy and transfer electrical energy from the solar cell 102 to the electrical device. The silicon layers 116 may include different dopant concentrations (e.g., p-type, n-type, intrinsic, etc.), crystal structures (e.g., microcrystalline, amorphous, etc.) and/or surface textures.

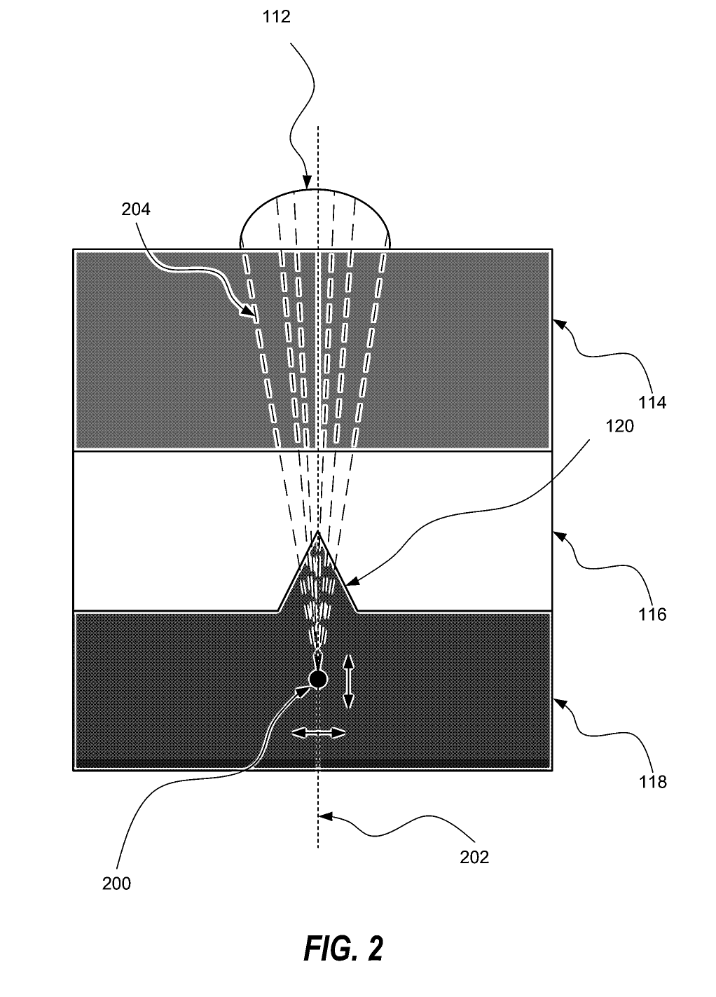

FIG. 2 illustrates one embodiment of a cross section of the solar cell 102 with a light concentration component 112 and a focal point 200 of the light concentration component 112 located in the reflector layer 118. In other embodiments, the focal point 200 may be located anywhere along the principal axis 202.

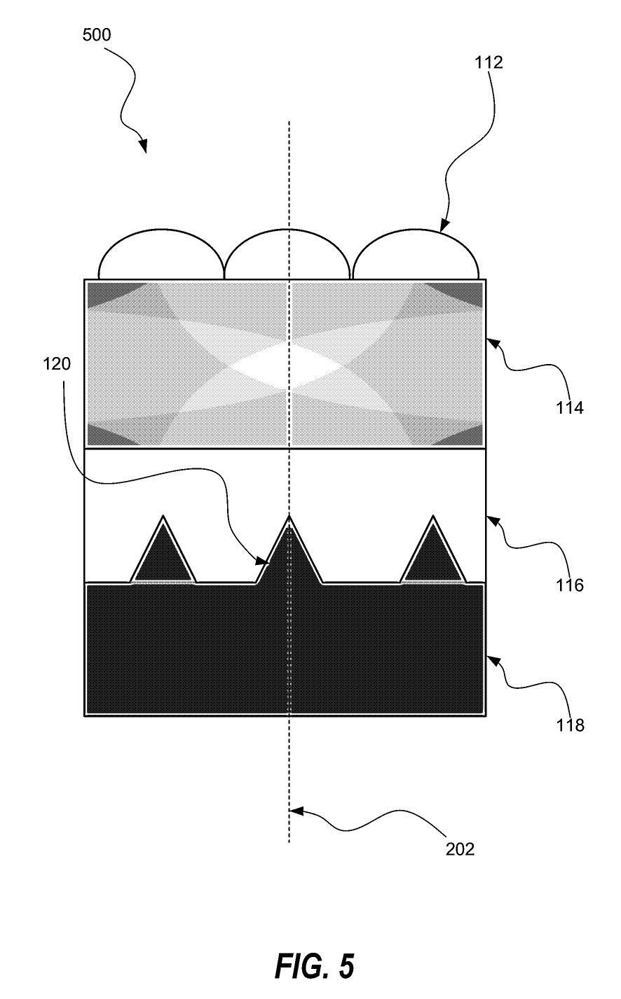

In the FIG. 2 embodiment, the light concentration component 112 may be made of a substantially transparent material, such as amorphous or crystalline ceramic, glass, plastic, formed either by photolithography, embossing, molding, or self assembly of particles that may allow light 106 to pass through into the substantially transparent layer 114 (e.g., glass). In this instance, the light concentration component 112 is symmetrical along a principal axis 202 that is aligned with the focal point 200. The design of the light concentration component 112 may be, but is not limited to, a spherical plano-convex lens which may have one side that is spherical and the opposite side may be substantially flat or conformal with the transparent layer 114. In other embodiments, the light concentration component 112 may be one of the following: biconvex, positive meniscus, negative meniscus, plano-concave, or biconcave. Alternatively, in other embodiments, the light concentration component 112 may be asymmetrical and the focal point 200 may be in any of the layers within the solar cell 102. In some embodiments, the light concentration component 112 may be part of an array as shown in FIG. 5.

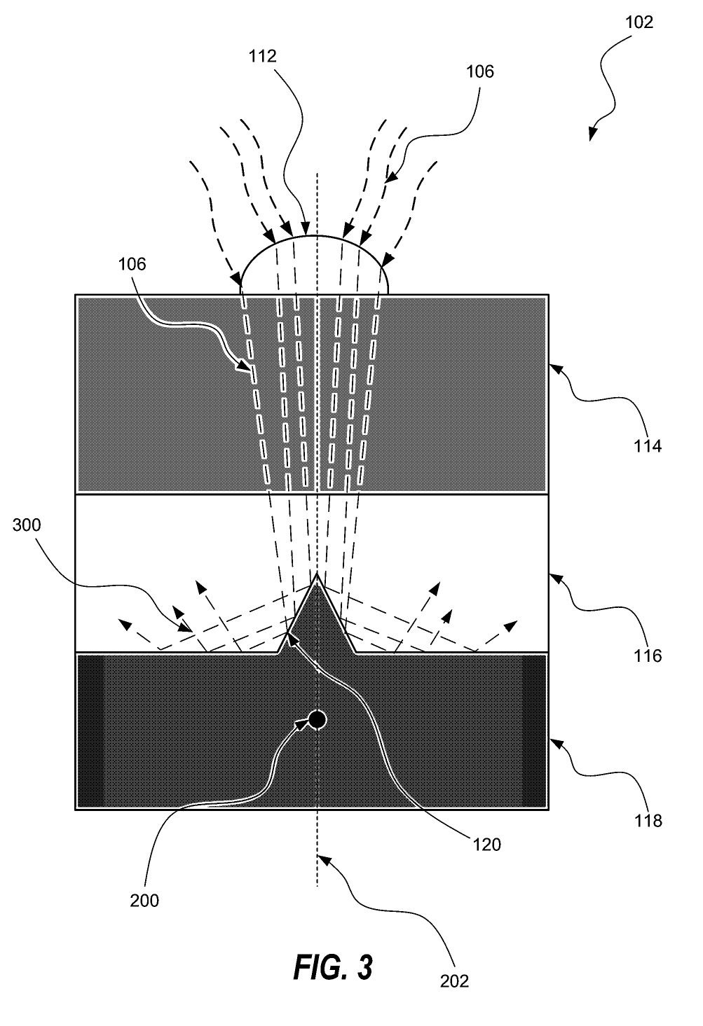

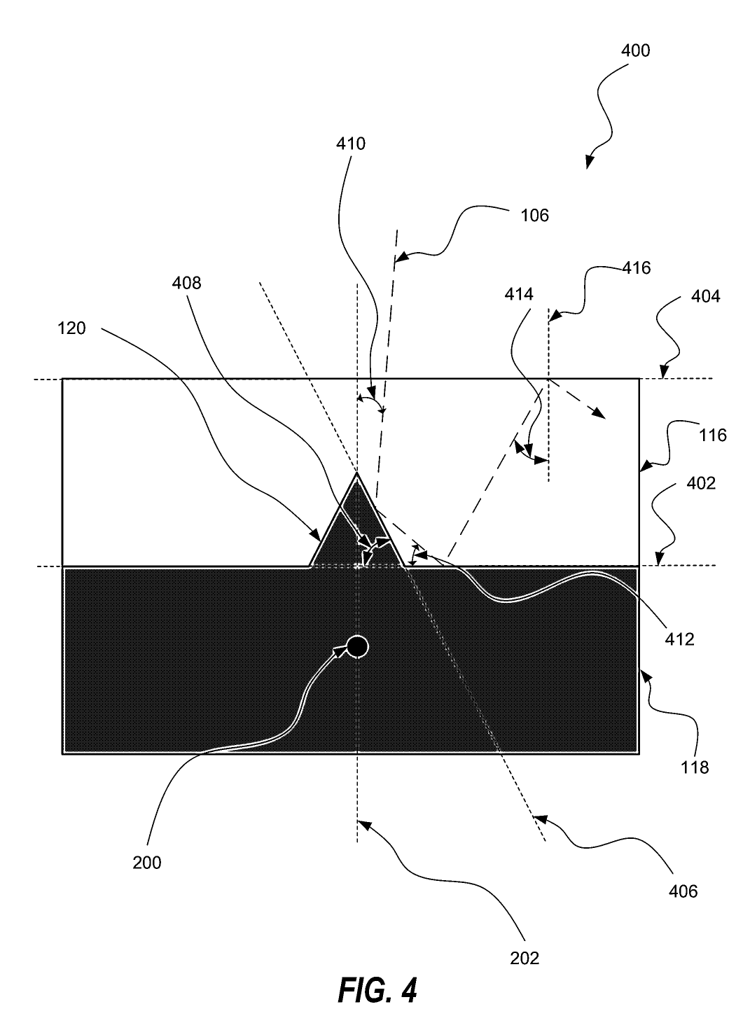

The focal point 200 may be the point on the principal axis 202 in which light 106 that passes through the light concentration component may converge together. The location of the focal point 200 may vary horizontally or vertically as shown in FIG. 2 depending on the type and/or design of the light concentration component 112. As shown in the FIG. 2 embodiment, the focal point 200 is located within the reflector layer 118 which results in the paths of light 106 intersecting the reflection notch 120 at different points and prior to converging at the focal point 200. In other embodiments, the light 106 may reflect off the reflection notch 120 in various directions, as shown in FIG. 3. Controlling the direction of the reflected light 106 may be based, at least in part, on the geometry of the reflection notch 120 and the location of the focal point 200. Ideally, a portion of the reflected light 106 may be reflected towards the reflector layer 118 and the silicon layer 116 in a way that enables the light 106 to be trapped within the silicon layer 116 under the principle of total internal reflection, as described in the description of FIG. 4.

The reflection notch 120, as shown in FIG. 2, is cross section of a pyramid-like or cone-like structure that protrudes up from the reflector layer 118 into the silicon layer 116. The reflection notch 120 may also be an angular cut or indentation into the silicon layer 116. The shape and geometry of the reflection notch 120 may vary depending the size and composition of the solar cell 102 in addition to the light concentration component 112 configuration. As noted above, the reflection notch 120 may be designed to reflect light 106 in manner that enables the light 106 to be confined within the silicon layer 116. This may allow additional electron-hole pairs (not shown) to be formed using the same photon of light 106. For example, light 116 may be reflected three or more times within the silicon layer 116 than when the reflection notch 120 is not present. An example of how this may be accomplished will be described in the description of FIG. 3.

FIG. 3 illustrates one embodiment of how light 106 may be reflected off the reflection notch 120 to enable total internal reflection within the silicon layer 116. In the FIG. 3 embodiment, a cross section of the solar cell 102 is shown with paths of light 106 passing through the solar cell 102 layers (e.g., transparent layer 114, etc.) to the reflection notch 120. The reflected light 300 may be reflected off the reflection notch 120 and then the surface of the reflector layer 118 back into the silicon layer 116. As noted in the description of FIG. 2, the light 106 converges towards the focal point 200 and impacts the reflection notch 120 which, in this embodiment, is above the focal point 200. Accordingly, the reflection notch 120 may include a single pyramid or cone, or a one direction light reflector. The apex of the element can have an angle varying from 0 to 80° with respect to the plane to induce a portion of the reflected light 300 to impact the transparent layer 114 surface for a second time at or below the critical angle (not shown) to maintain total internal reflection of the light 106 within the silicon layer 116. The critical angle (not shown) for implementing total internal reflection will be discussed in the description of FIG. 4.

FIG. 4 illustrates a modified solar cell 400 that only shows the silicon layer 116 and the reflector layer 118 of the solar cell 102 for the purpose of ease of explanation of the solar cell 102 design. The modified solar cell 400 highlights several surfaces that may be used to measure angles related to light incidence or reflection notch 120 geometry. These surfaces are merely one example of how the solar cell 102 may be designed to facility total internal reflection of light 106 within the silicon layer 116.

They surfaces may include, but are not limited to, a reflector layer surface 402 at the silicon layer 116 and reflector layer 118 interface, a silicon layer surface 404 at the silicon layer 116 and transparent layer 114 (not shown) interface. The reflection notch surface 406 may also be at the silicon layer 116 and reflector layer 118 interface, but may not be on the same plane as the reflector layer surface 402. Although all of the surfaces are shown as planar, they are not required to be absolutely planar and may have significant non-uniformity. In which case, the surface planes may be approximated to a plane that is an average or a mean of the surface that forms the silicon layer 116 and reflector layer 118 interface or the silicon layer 116 and transparent layer 114 (not shown) interface that may refract or reflect light 106.

The reflection notch angle 408 may represent how much the reflection notch 120 may protrude from the reflector layer 118 into the silicon layer 116. In one embodiment, the reflection notch angle 408 may be measured between the intersection of the reflector layer surface 402 and the reflection notch surface 406. The reflection notch angle 408 may range between 15° and 80° and may vary in view of the focal point 200, the light concentration component 112, the incident light angle 410, the reflected angle 412, and the critical angle 414.

The incident light angle 410 may represent the angle between the intersection of the principal axis 202 and the light 106 that is incident upon the reflection notch 120. The intersection may be at the focal point 200. Generally, there may be not set absolute value for each instance of light 106 (e.g., light 106 in FIG. 3) but may include a range of 0° to 70° in view of the reflection notch angle 408 and the critical angle 414. The incident light 106 may be reflected towards the surface of the reflector layer 118 and be reflected again toward the silicon layer based, at least in part, on the reflected light angle 412.

The reflected light angle 412 may represent the angle between the intersection of the reflector layer surface 402 and the reflected light 106 from the reflection notch 120. The incident light angle 410 and the reflection notch angle 408 may have a relatively large impact on the reflected light angle 412. For total internal reflection, the incident light angle 410 may be lower than 2 times the reflection notch angle 408 minus the critical angle 414. The light 106 reflected back into the silicon layer 116 may also induce additional electron-hole pair generation. However, to generate more electron-hole pairs the light 106 may need to be reflected back into the silicon layer 116 when the light intercepts the transparent/silicon layer interface. Under the principle of total internal reflection, the light may intercept the transparent/silicon layer interface at a critical angle 414.

The critical angle 414 determines whether the incident light may reflect back into the silicon layer 116 when the light 106 reaches the silicon-transparent layer interface. The critical angle 414 may be equal to or greater than the critical angle 414 to enable the light 106 to be reflected into the silicon layer 116 and not refracted into the transparent layer 114 (not shown). As noted above in the description of FIGS. 1-3, the complete or substantially complete reflection of the light 106 falls under the principle of total internal reflection. In this way, the light 106 may continue to reflect or travel through the silicon layer 116 without substantially crossing into the transparent layer 114 or the reflector layer 118. The additional time spent in the silicon layer 116 may result in a higher amount of electron-hole pairs being generated than if the light 106 was refracted out of the silicon layer 116 into the transparent layer 114. The critical angle 414 should be less than a predetermined amount that may be based, at least in part, on index of refraction of the transparent layer 114 and the silicon layer 116. The critical angle 414 (θ_{C}) may be determined based on the following equation:

$${θ}_{C} = arcsin ( \frac{{n}_{2}}{{n}_{1}} )$$

Wherein n₂ is the index of refraction for the transparent layer 114 and n₁ is the index of refraction for the silicon layer 116. The critical angle 414 may be measured from a perpendicular plane 416 that extends out from the point of intersection between the light 106 and the silicon-transparent layer 114 interface or the silicon layer surface 404. The material for total internal reflection could be metal or ceramic.

In some embodiments, the solar cell 102 may include multiple reflection notches 120 to enable total internal reflection of light 106 throughout a larger surface area than the solar cell 102 shown in FIGS. 1-4. FIG. 5 illustrates a solar cell 500 that includes a plurality of light 106 reflection features over a surface area as shown in solar cell 500. To minimize escape of light from reflection with another reflection notch, the distance between two notches 120 may be larger than the thickness of the layer 116. In the FIG. 5 embodiment, the solar cell 500 is shown in cross section with several light concentration components 112 aligned next to each other and on top of the transparent layer 114. In this instance additional (not shown) light concentration components 112 may be arranged across the surface of the transparent layer 114 in several directions.

In one embodiment, the light concentration components 112 may each include a corresponding reflection notch 120 that aligned along the principal axis 202. In this way, each of the reflection notches 120 may be able to reflect light 106 in a way that may enable total internal reflection as described above in the description of FIGS. 1-4. However, in other embodiments, each of the light concentration components 112 may not each have their reflection notch 120. The density of the reflection notches 120 may be lower to facilitate or maintain total internal reflection of light 106 over a longer distance within the silicon layer 116. The additional reflection notches 120 may interfere or alter the angle of light that may have already been reflected back from the transparen layer 114. Accordingly, there may be one or more adjacent light concentration components 112 that may not have a reflection notch 120 aligned along the principal axis 202 of the light concentration component 112.

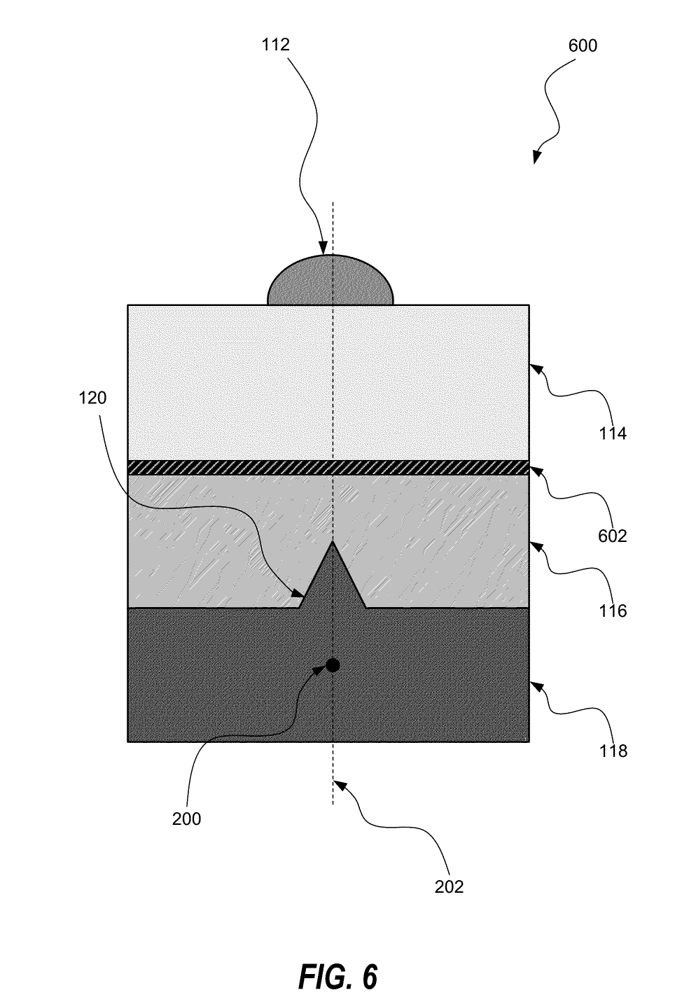

Solar cell 102 is not limited to the layers shown in FIGS. 1-5 and may include one or more additional layers between any of the other layers. FIG. 6 illustrates another embodiment of a solar cell 600 that may include an oxide layer 602 in between the transparent layer 114 and the silicon layer 116. The metal-oxide layer 602 may include, but is not limited to, a metal oxide that is substantially transparent (e.g., transparent conductive oxide) and may include a polycrystalline or an amorphous microstructure. The metal-oxide layer 602 can include, but is not limited to, aluminum-doped zinc oxide, tin-doped indium zinc oxide, and tin-doped cadmium oxide. Additional dopants that may be incorporated into a metal oxide may include, but is not limited to: F, Nb, Ga, Ge, Hf, Mg, Mo, Ta, Y, Zr, W, B, V, Ti, and As. In other embodiments, an additional metal-oxide layer (not shown) may be between the silicon layer 116 and the reflector layer 118.

Manufacturing the solar cell 600 may be done using selective etching techniques to form the reflection notch 120. The selective etching methods may include patterning processes that may designate which portions of the substrate that may be etched or left in place. Prior to and after the selective etching, one or more cleaning processes may also be used to prepare the substrate for patterning and etching and/or post-etch cleaning. Selective etching or removal of material may be accomplished through photolithography patterning and plasma etching or laser ablation.

Photolithography may include using light sensitive films to put a sacrificial pattern on top of the substrate and plasma etching may be used to remove portions of the substrate that are not covered by the pattern. Laser ablation may include using a laser to etch a pattern into the substrate. This may involve moving the laser along the substrate that may remove portions of the substrate where the laser contacts the substrate.

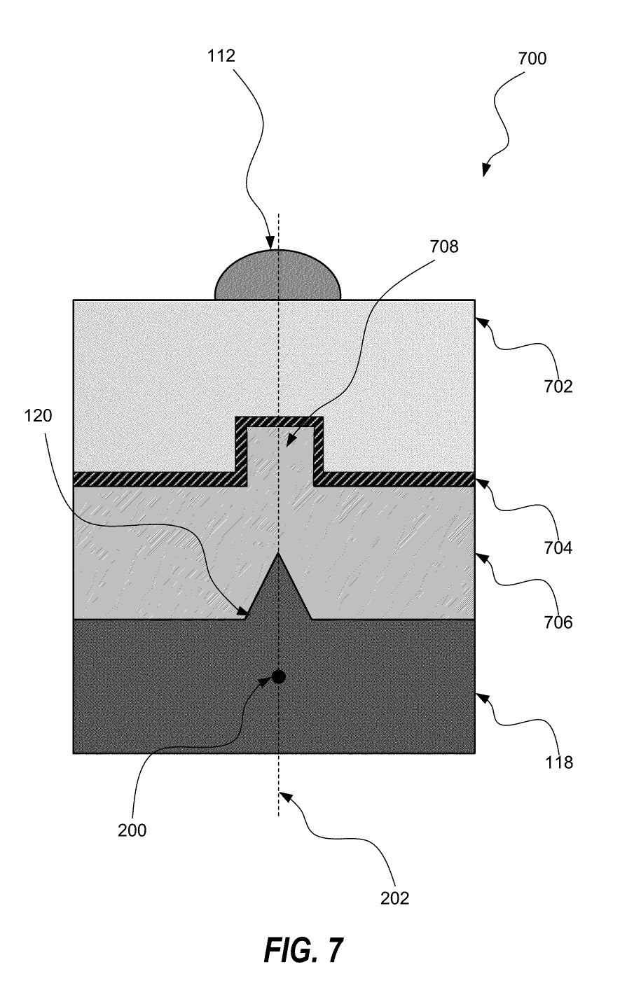

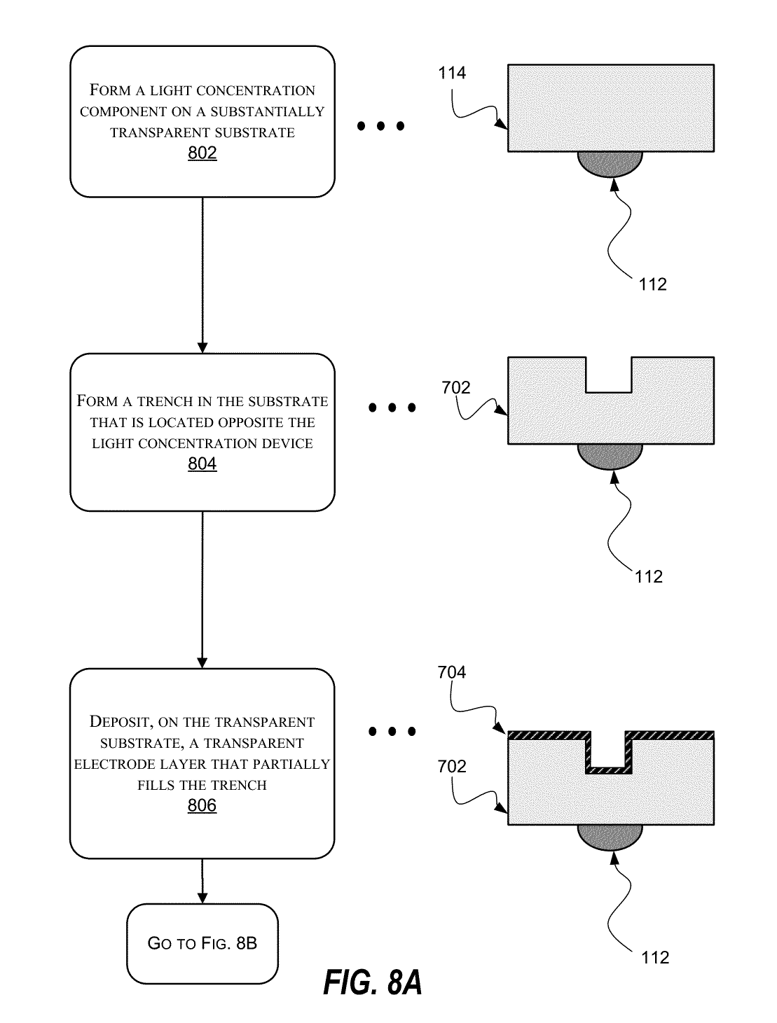

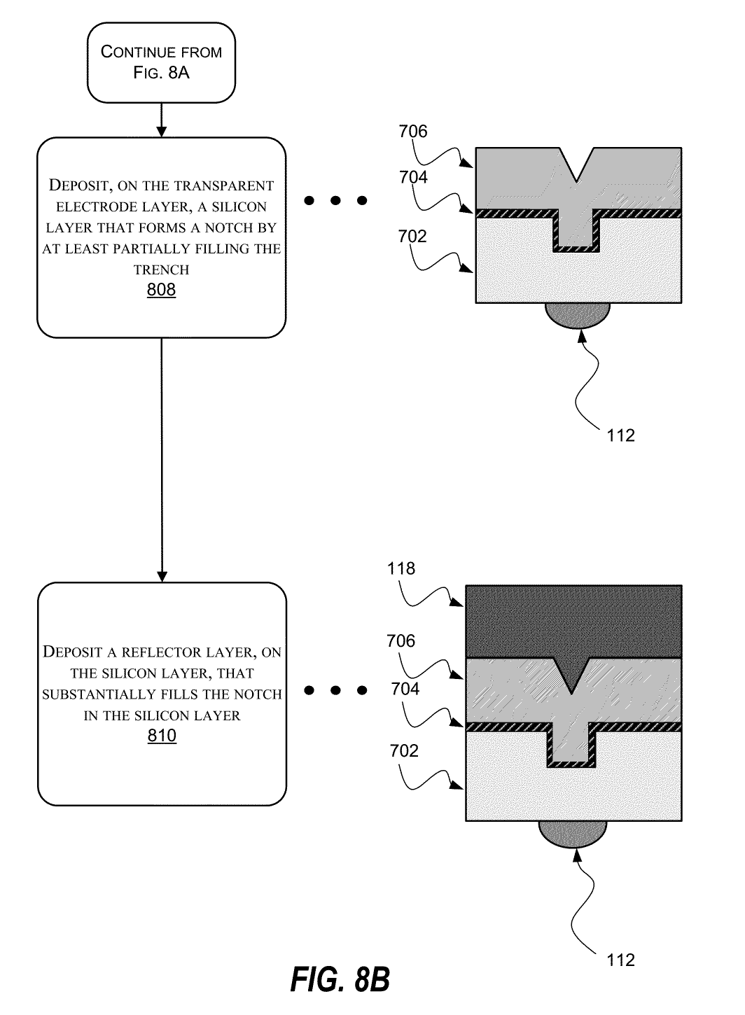

In view of the aforementioned solar cell 102 design, the alignment of the light concentration component 112 and the reflection notch 120 may be needed. However, selectively etching multiple layers, or even one layer, to align with other features in the solar cell 102 may be costly and time consuming. One embodiment that may reduce manufacturing cost and time may include a self-aligned process that assists with aligning the features of the solar cell 102. One embodiment of the self-aligned solar cell 700 will be described in the description of FIG. 7, while one specific manufacturing method that will be described in the description of FIGS. 8A-8B.

FIG. 7 illustrates one embodiment of a self-aligned solar cell 700 that may be manufactured using a self-aligned process that may substantially align the light concentration component 112 with the reflection notch 120 and focal point 200 on the principal axis 202. Again, the solar cell 700 may include additional layers that are not shown in FIG. 7 and are not shown here for the purpose of ease of explanation of the of solar cell 700 structure.

In contrast to solar cell 600, the self-aligned solar cell 700 may include an alignment notch 708 in the transparent substrate layer 702 that may be similar to the transparent substrate 114. The alignment notch 708 may be aligned with the light concentration component 112 during the selective etching process (e.g., laser ablation). For example, the laser may be shot through the light concentration component 112 to remove a portion of the transparent layer 702 that is opposite the light concentration component 112. The laser may travel through the transparent layer 702 to remove a portion of material that on the opposite side from the light concentration component.

The alignment notch 708 may include a metal-oxide layer 704 that may be similar to the metal-oxide layer 602 described in the description of FIG. 6. In this embodiment, the metal-oxide layer 704 fills a portion of the reflection notch 120 with the remainder being filled by the silicon layer 706. In this embodiment, the oxide layer 702 is very conformal with the alignment notch 708. As shown, the metal-oxide layer 704 follows the form of the alignment notch 708 very closely. This may be due to the thickness of the metal-oxide layer 704. In contrast, the silicon layer 116 may be thicker than the metal-oxide layer 704 and may be less conformal with the alignment notch 708. For example, the silicon layer 116 may have to fill a larger portion of the alignment notch 708 than the metal-oxide layer 704. As a result, the silicon layer surface 404 that is opposite the alignment notch 708 may form a divot or notch that may be filled by the reflector layer 118 to form the reflection notch 120. The reflection notch may be formed using other techniques and the description of FIG. 7 is one specific embodiment used to form the self-aligned solar cell 700.

FIGS. 8A-8B illustrates a flow diagram of a method 800 to manufacture a self-aligned solar cell 700. The method 800 also includes corresponding illustrations next to each description of the method 800. The solar cell 700 may be manufactured using a self-aligning strategy between the light concentration component 112 and the reflection notch 120, such that the focal point 200 for the light concentration component 112 is also substantially aligned with the reflection notch 120. The method 800 is one embodiment for generating the solar cell 700 and the step order may be configured differently and may include additional steps or omit steps in the illustrated method 800.

At step 802, a transparent substrate 114 for a solar cell 700 may have a light concentration component 112 formed on one of its surfaces. In the illustrated embodiment, a single light concentration component 112 is shown. However, in other embodiments, two or more light concentration components 112 may be adjacent to each other, as shown in FIG. 5. The transparent substrate 114 may include, but is not limited to, glass that will enable light 106 to pass through from one side of the glass to another side of the glass. The light concentration component 112 may be coupled to or adhered to the surface of the glass. Similarly, light 106 should be able to pass through the light concentration component 112 and enter the glass. The light concentration component 112 may be enable to focus incident light 106 towards a focal point 200. As noted above in the description of FIG. 1, the light concentration component 112 may include, but is not limited to, a spherical plano-convex lens that may receive light 106 along a spherical portion of the lens and reflect the light 106 towards substantially flat side of the lens. The substantially flat portion may be coupled to the glass. The lens may be a transparent material, as amorphous or crystalline ceramic, glass, plastic, formed either by photolithography, embossing, molding, or self assembly of particles.

The light concentration component 112 may have a focal point 200 that needs to be aligned with a reflection notch 120 that may be formed by a blanket film deposition process without selectively etching that the deposited film. In this embodiment, the self-alignment may use the light concentration component 112 to pattern the transparent substrate 114 in a way that forms the reflection notch 120 using a blanket deposition process for the reflector material.

At step 804, a trench may be formed in the transparent layer 702 by using a laser that is focused by the light concentration component 112. The laser ablation may remove a portion of the transparent layer 702 that is on the opposite side from the light concentration component 112. In one embodiment, the laser may be configured to form the trench so that the trench width is greater than the trench depth. The aspect ratio trench depth over trench width may be lower 0.5 and with a depth in the range 0.5 micron to 40 microns. The trench may include two opposing surfaces that form the trench depth and another surface connected to the two opposing surfaces. The connecting surface may represent the trench width. The trench width and depth may vary to accommodate various sizes of the reflection notch 120. A deeper trench may increase the height of the reflection notch 120 and a wider trench may increase the width of the reflection notch 120. Generally, the trench surfaces may be configured to adhere to an overlying film.

At step 806, a transparent electrode layer 704 or metal-oxide layer may be deposited on the transparent substrate 702 and may, at least, partially fill the trench. The fill may be substantially conformal to the trench features and may be a less thickness than the transparent substrate 702 thickness. The transparent electrode layer 704, as described in FIGS. 6-7, may be a metal-oxide that may be doped with one or more materials. The transparent electrode layer 704 may be configured to transmit incident light 106 from the metal-oxide/glass interface to the opposite side of the metal-oxide layer and into another film layer that may be adhered to the metal-oxide layer.

At step 808, a silicon layer 706 may be deposited on the transparent electrode layer 704 and may fill the remainder of the trench in a substantially conformal manner. A notch in the silicon layer 706 may be formed by the silicon layer 116 as a result of conforming to the trench. As shown in the corresponding diagram, the notch may be opposing the trench from the upper surface of the silicon layer 116. Although substantially triangular in the cross section illustration, the notch may be substantially conical or pyramid-like in three dimensions. The notch geometry may be based, at least in part, on the trench width, trench depth, trench length, and the deposition rate of the silicon layer(s) 116. As noted in the description of FIG. 1, the silicon layer 116 may be a combination of multiple silicon layers 116 with differing dopant concentrations and/or microcrystalline structures. The silicon layer 116 may also transmit light 106 from the metal-oxide/silicon interface towards the notch and to a film layer that may fill the notch.

At step 810, the reflector layer 118 may be deposited over the silicon layer 116 and substantially fills the notch in the silicon layer 116. The reflector layer 118 may form the reflection notch 120 by filling the notch in the silicon layer 116. The reflection notch 120 may reflect substantial portion of light 106 from the silicon layer 116 towards the reflector/silicon interface that may surround the reflection notch 120. As noted in the description of FIGS. 2-5, the light 106 may be reflected from the reflector/silicon interface (e.g., reflector layer surface 402) towards the metal-oxide/silicon interface (e.g., silicon layer surface 404). The reflection notch 120 and the focal point 200 may be arranged to reflect light 106 at an angle that may enable total internal reflection within the silicon layer 116. As described in the description of FIG. 4, total internal reflection may mean the light 106 that intersects the metal-oxide/silicon interface (e.g., silicon layer surface 404) at or less than the critical angle 414 may be completely reflected back into the silicon layer 116. In this way, the energy conversion process may be made more efficient by using the same photon of light 106 three or more times instead of just twice.

Although only certain embodiments of this application have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A solar energy conversion device, comprising:
a concentration lens that can refract incident light to a focal point;
a transparent glass layer that is coupled to the concentration lens;
a light confinement layer that is adjacent to the transparent glass layer, the light confinement layer comprising:
a silicon layer; and
a reflection notch in the silicon layer that is located near the focal point; and
a reflector layer that is coupled to the light confinement layer and substantially fills the reflection notch that is configured to reflect at least a portion of the incident light into the silicon layer.

2. The device of claim 1, wherein the silicon layer comprises a doped amorphous silicon layer, a doped microcrystalline silicon layer, and amorphous silicon layer comprising a doping concentration that is lower than a doping concentration in the doped amorphous silicon layer.

3. The device of claim 1, further comprising a transparent electrode layer disposed between the light confinement layer and the transparent glass layer.

4. The device of claim 1, wherein the reflected portion of incident light comprises a reflection angle that enables total internal reflection within the light confinement layer.

5. The device of claim 1, wherein the reflection notch comprises a surface that is angled between 25 degrees and 75 degrees from a surface of the transparent electrode layer or the light confinement layer.

6. The device of claim 1, wherein the reflection notch comprises an angular cut or indentation that runs along the silicon layer in a substantially linear manner.

7. A solar energy conversion device, comprising:
a concentration lens that can refract incident light to a focal point;
a transparent glass layer that is coupled to the concentration lens, the transparent glass layer comprising a trench that is substantially aligned with the focal point;
a light confinement layer comprising:
a silicon layer;
a notch in the silicon layer that is substantially aligned with the focal point and the trench; and
a portion of the silicon layer that is in the trench;
a transparent electrode layer disposed between the light confinement layer and the transparent glass layer, the transparent electrode layer comprising a portion that is in the trench; and
a reflector layer that is coupled to the light confinement layer and substantially fills the notch, the reflector layer is configured to reflect the incident light within the light confinement layer.

8. The device of claim 7, wherein the trench comprises a depth that is smaller than a width of the trench.

9. The device of claim 7, wherein the substantial alignment comprises a vertical plane that intersects a portion of the notch, a portion of the concentration lens, and the focal point.

10. The device of claim 7, wherein the silicon layer comprises a doped amorphous silicon layer, a doped microcrystalline silicon layer, and amorphous silicon layer comprising a doping concentration that is lower than a doping concentration in the doped amorphous silicon layer.

11. The device of claim 7, wherein the concentration lens comprises a transparent material, such as amorphous or crystalline ceramic, glass, or plastic.

12. The device of claim 7, wherein the transparent electrode layer comprises a metal oxide composition that includes one or more of the following materials: aluminum, zinc, tin, or indium.

13. The device of claim 7, wherein the reflector layer comprises a surface that is angled approximately 45 degrees from a surface of the transparent electrode layer or the light confinement layer.

14. The device of claim 7, wherein the reflector layer is arranged to reflect light at a critical angle that enables total internal reflection within the light confinement layer.

15. A method for manufacturing amorphous silicon solar cell, comprising:
forming a light concentration component on a substantially transparent substrate;
forming a trench in the substantially transparent substrate that is located opposite the light concentration component;
depositing, on the substantially transparent substrate, a transparent electrode layer that partially fills the trench;
depositing, on the transparent electrode layer, a silicon layer that forms a notch by at least partially filling the trench; and
depositing a reflector layer, on the silicon layer, that substantially fills the notch in the silicon layer.

16. The method of claim 15, wherein the forming of the light concentration component comprises arranging a substantially transparent material on the surface of the transparent substrate to form a focal point for light that passes through the light concentration component.

17. The method of claim 16, wherein the focal point is near the notch or inside the notch.

18. The method of claim 15, wherein the forming of the trench comprises removing a portion of the transparent substrate such that a trench width that is smaller than a trench depth in the transparent substrate.

19. The method of claim 15, wherein the silicon layer comprises a doped amorphous silicon layer, a doped microcrystalline silicon layer, and amorphous silicon layer comprising a doping concentration that is lower than a doping concentration in the doped amorphous silicon layer.

20. The method of claim 15, wherein the silicon layer comprises a thickness that is less than or equal to 20 microns.
